(19) United States
(12) Patent Application Publication
(10) Pub. No.: US 2013/0093072 A1
(43) Pub. Date: Apr. 18, 2013

(54) LEADFRAME PAD DESIGN WITH ENHANCED ROBUSTNESS TO DIE CRACK FAILURE

(71) Applicants: Xueren Zhang, Singapore (SG); Wingshenq Wong, Singapore (SG); Kim-Yong Goh, Singapore (SG); Yiyi Ma, Singapore (SG)

(72) Inventors: Xueren Zhang, Singapore (SG); Wingshenq Wong, Singapore (SG); Kim-Yong Goh, Singapore (SG); Yiyi Ma, Singapore (SG)

(73) Assignee: STMICROELECTRONICS PTE LTD., Singapore (SG)

(21) Appl. No.: 13/273,027

(22) Filed: Oct. 13, 2011

(51) Int. Cl. H01L 23/495; H01L 21/56

(52) U.S. Cl. 257/676; 438/118; 257/E23.052; 257/E21.502

(57) ABSTRACT

A leadframe includes a die pad and a protective wall surrounding the die pad. A semiconductor die is situated on the die pad. Indentations are formed on the four inner corners of the protective wall adjacent the corners of the semiconductor die.

### BACKGROUND

1. Technical Field

The present application relates to the packaging of a semiconductor die and more particularly to the protection of a semiconductor die within a package.

2. Description of the Related Art

Integrated circuits are formed from semiconductor dice that have been processed to form electronic circuitry therein. Before integrated circuits are put into commercial application, they are generally packaged in such a way to protect the semiconductor die therein. Integrated circuits can be packaged in a variety of ways. Integrated circuits may be packaged as leadframes, ball grid arrays, on organic substrates, pin grid arrays, and in a large variety of other types of packages.

FIG. 1 illustrates a semiconductor package 20 according to the prior art. Semiconductor package 20 includes a wall 22 surrounding a semiconductor die 24. The integrated circuit package includes leads 25. Leads 25 are connected to the semiconductor die 24 by bonding wire (not shown in FIG. 1).

FIG. 2 illustrates a cross section of the semiconductor package 20 of FIG. 1. The semiconductor die 24 is coupled to a die pad 26 by an adhesive paste 28. The semiconductor die 24, the protective wall 22, bonding wires 23, and portions of the leads 25 are covered in a molding compound 27. In one embodiment, the protective wall 22 and the die pad 26 are formed of a conductive material such as copper. When the semiconductor die 24 is attached to the die pad 26, the adhesive paste 28 is displaced. If no protective wall 22 is present, then the adhesive paste spills off of the side of the die pad 26. With the protective wall 22 in place as shown in FIG. 2, the adhesive paste is displaced such that some portion of it overflows to the top surface of the protective wall 22.

### BRIEF SUMMARY

One embodiment is an integrated circuit package including a semiconductor die placed on a substrate. The semiconductor die is surrounded by a protective wall. The semiconductor die is attached to the substrate by an adhesive material.

In one embodiment, indentations are formed on the inner corners of the protective wall adjacent the corners of the semiconductor die. When the semiconductor die is placed on the adhesive material on the substrate, the adhesive material is displaced into the indentations. This inhibits the adhesive paste from spilling up and over the top of the protective wall. This also helps to provide a flat surface on which the semiconductor die may rest.

In one embodiment, indentations are formed on inner side surfaces of the protective wall. When the semiconductor die is placed on the adhesive material, the adhesive material is displaced and fills the indentations on the inner side surfaces of the protective wall. This inhibits the adhesive material from spilling up and over the protective wall. This also inhibits uneven buildup of the adhesive material near the protective wall. This provides a more flat surface on which the semiconductor die can rest.

In one embodiment, a groove is formed in the substrate below where the semiconductor die will be attached. When the semiconductor die is placed on the adhesive material, the adhesive material is displaced and fills the groove. This helps to prevent the adhesive material from spilling up and over the protective wall. This also helps prevent the adhesive material from forming an uneven buildup near the protective wall. This helps to provide a flat surface on which the semiconductor die can rest. In one embodiment, the groove has a narrow and shallow cross section and extends in a rectangular or circular pattern on an area of the substrate on which the semiconductor will rest.

In one embodiment, the semiconductor package is a leadframe package. In one embodiment, the semiconductor package is a ball grid array package, pin grid array package, or extended wafer level ball grid array package. In one embodiment, the substrate is an organic substrate. In one embodiment, the substrate conducts both heat and electricity. In one embodiment, the adhesive material is solder, while in others the adhesive material is an adhesive paste or glue.

### BRIEF DESCRIPTION OF THE SEVERAL VIEWS OF THE DRAWINGS

FIG. 1 illustrates a top view of a conventional integrated circuit package.

FIG. 2 illustrates a cross section of the integrated circuit package of FIG. 1 taken along lines 2-2.

FIG. 3 illustrates a top view of an integrated circuit package without a semiconductor die present.

FIG. 4 illustrates a top view of an integrated circuit package according to one embodiment.

FIG. 5 illustrates a cross section of the integrated circuit package of FIG. 3 taken along lines 5-5 according to one embodiment.

FIG. 6 illustrates a top view of an integrated circuit package according to one embodiment.

FIG. 7 illustrates a top view of an integrated circuit package including a semiconductor die according to one embodiment.

FIG. 8 illustrates a cross section of the integrated circuit package of FIG. 7 taken along lines 7-7 according to one embodiment.

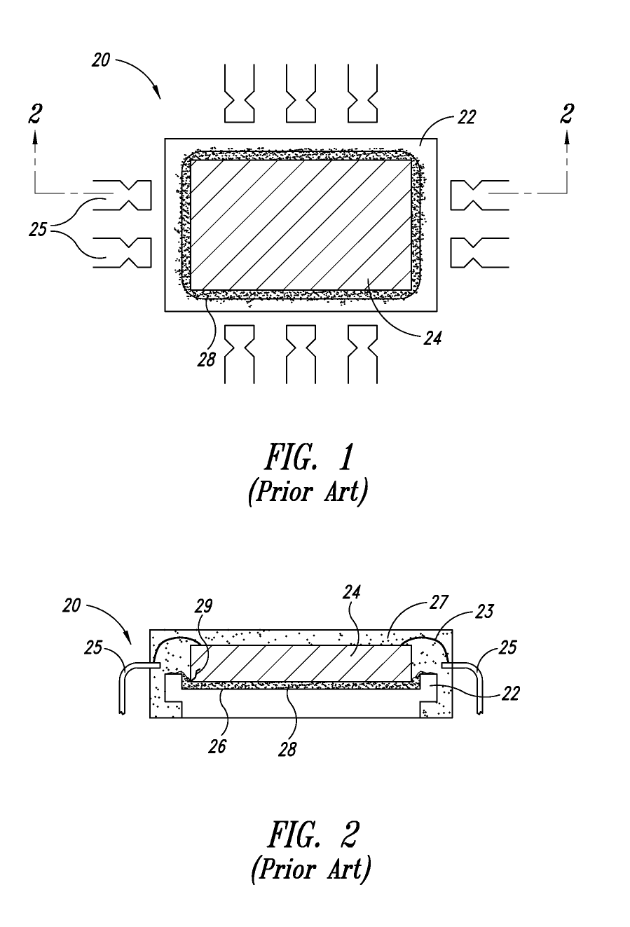

### DETAILED DESCRIPTION

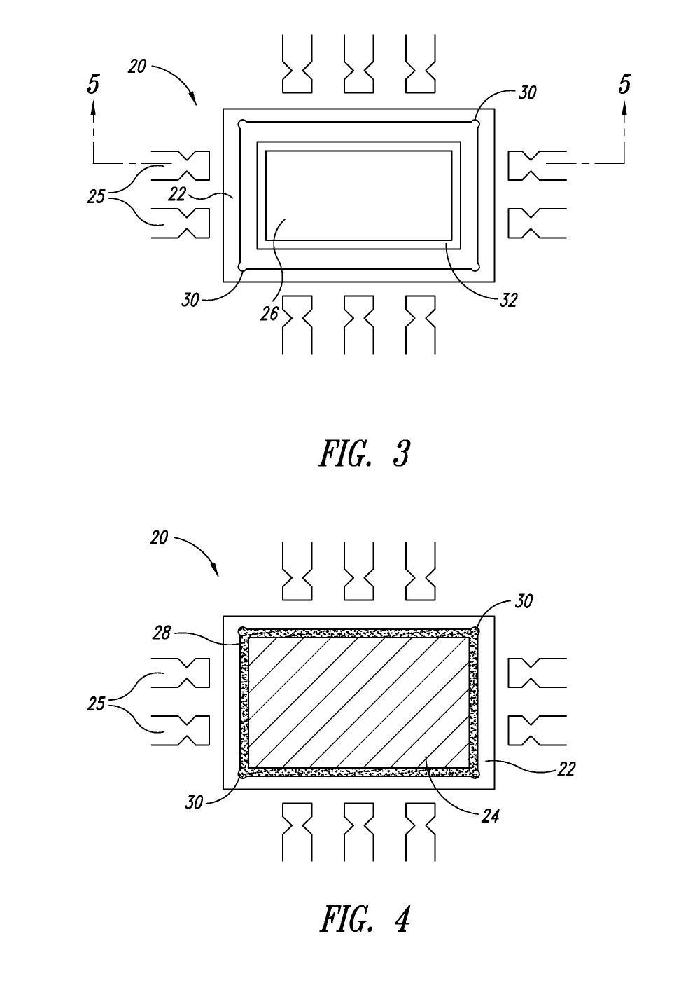

FIG. 3 illustrates an integrated circuit package 20 including a die pad 26 on which a semiconductor die 24 will be placed. A protective wall 22 surrounds the die pad 26. Conductive leads 25 surround the protective wall 22. Indentations 30 have been formed in the inner corners of the protective wall 22. A groove 32 has been formed in the top surface of the die pad 26. The groove 32 is formed on an area of the die pad 26 above which the semiconductor die 24 will be placed.

The indentations 30 provide a space into which adhesive material 28 can flow when the semiconductor die 24 is placed on the adhesive material 28 to attach the semiconductor die 24 to the die pad 26. The groove 32 provides space into which the adhesive material 28 can flow when the semiconductor die 24 is placed thereon.

FIG. 4 illustrates the integrated package 20 of FIG. 3 after the semiconductor die 24 and the adhesive material 28 have been placed on the die pad 26 according to one embodiment. The integrated circuit package 20 of FIG. 4 includes the integrated circuit 24 placed on a die pad 26. The semiconductor die 24 is attached to the die pad 26 by the adhesive material 28. In one embodiment, the adhesive material 28 is solder. The leads 25 are connected to the integrated circuit 24 by bonding wire (shown in FIG. 8). The semiconductor die 24 may also be connected by bonding wire to the protective wall 22. The protective wall 22, thus, acts as a ground connection for the semiconductor die 24.

When the semiconductor die 24 is placed on the adhesive material 28, the adhesive material 28 is displaced and fills the indentations 30. The adhesive material also fills the groove 32 not visible in FIG. 4. Because the adhesive material 28 is able to flow into the indentations 30 and groove 32, the adhesive material 28 does not have uneven buildup near the protective wall 22. An uneven buildup of the adhesive material 28 can create an uneven surface on which the semiconductor die 24 rests. If the surface on which the semiconductor die 24 rests is uneven, then stresses can be exerted on the edges and, in particular, to corners of the semiconductor die 24. These stresses may cause semiconductor die 24 to bend. This bending eventually can cause cracking of the semiconductor die 24. When the semiconductor die 24 cracks, functionality of the semiconductor die 24 may be lost.

Because the adhesive material 28 is able to flow into the indentations 30, the adhesive paste does not have uneven buildup near the protective wall 22. An uneven buildup of the adhesive material 28 can create an uneven surface on which the semiconductor die 24 rests. If the surface on which the semiconductor die 24 rests is uneven, then stresses can be exerted on the edges and, in particular, to corners of the semiconductor die 24. These stresses may cause the semiconductor die 24 to bend. This bending can eventually cause cracking of the semiconductor die 24. When the semiconductor die 24 cracks, functionality of the semiconductor die 24 may be lost. The indentations 30 also provide increased space between the corners of the semiconductor die 24 and the protective wall 22. This increased spacing can prevent contact between the semiconductor die 24 and the protective wall 22. Any contact between the semiconductor die 24 and the protective wall 22 can cause damage and loss of functionality to the semiconductor die 24.

A molding compound (not shown in FIG. 4) encapsulates the integrated circuit package 20. If the adhesive material 28 flows onto a top portion of the protective wall 22, then the molding compound may form poor adhesion with the protective wall 22. In one embodiment, the protective wall 22 is formed of copper. Molding compound adheres to copper better than it does to most adhesive materials 28. Therefore, if the adhesive material is on a top surface of the protective wall 22, the molding compound may adhere poorly with the protective wall 22. This poor adhesion may cause delamination of the molding compound from the protective wall. The delamination can spread to other parts of the integrated circuit package 20. Such a delamination can allow humidity to enter into the integrated circuit package 20 and to damage the semiconductor die 24. Delamination can also cause stresses on the semiconductor conductor 24 which can cause the semiconductor die to function poorly or to crack and not function at all. Because indentations 30 are formed on the inner corners of the protective wall 22, the adhesive material 28 does not spill over the top of the protective wall 22. This allows for strong lamination between the molding compound and the protective wall 22.

The indentations 30 may be formed in the protective wall by any suitable method. The indentations 30 may be formed by etching the protective wall 22, by initially forming the protective wall 22 with indentations in place, or by stamping the protective wall 22. Many other methods may be employed to form the indentations 30 as will be apparent to those of skill in the art in light of the present disclosure.

FIG. 5 is a cross section of the integrated circuit package 20 of FIG. 3 taken along lines 5-5. Groove 32 is formed in the die pad 26 of the integrated circuit package 20. In one embodiment, the groove 32 is between 100 and 200 μm wide and between 100 and 200 μm deep. The groove 32 is formed in the top surface of the die pad 26 such that the groove 32 will be near the edges of the semiconductor die 24 when the semiconductor die is placed on the die pad 26. In one embodiment, the groove 32 is formed by stamping the die pad 26. Alternatively, the groove 32 may be formed by etching the die pad 26 in the desired pattern. While the groove 32 is shown as having a rounded cross section, the cross section of the groove 32 may be square, triangular, uneven, or any other suitable cross section. Furthermore, while the groove 32 is shown as extending in a rectangular pattern as a single, contiguous groove around an outer portion of the die pad 26, the groove 32 may also be one or more individual grooves 32 formed in the surface of the die pad 26. For example, four separate grooves 32 may be formed in the die pad 26. Two grooves 32 may each extend along the respective long edges of the die pad 26. Two other grooves 32 may extend along the respective short edges of the die pad 26. Many other configurations of the groove 32 are possible as will be apparent to those of skill in the art in view of the present disclosure.

FIG. 6 illustrates a top view of an integrated circuit package 20 according to one embodiment. FIG. 6 illustrates the corner indentations 30 described in relation to FIG. 3, as well as the groove 32 described in relation to FIGS. 4 and 5. Side indentations 34 are also formed along inner side surfaces of the protective wall 22. The side indentations 34 may be of a similar size to the corner indentations 30. Alternatively, the side indentations 34 may be bigger or smaller than the corner indentations 30. In one example, the side indentations 34 are about 100 μm in radius. When the semiconductor die 24 is placed on the die pad 26, the adhesive material 28 will be displaced and fill the side indentations 34. This helps to prevent an uneven buildup of the adhesive material 28 next to the protective wall 22 and to provide a flat surface on which the semiconductor die 24 may be placed. While FIG. 6 illustrates four side indentations 34 along each of the long inner side surfaces of the protective wall 22, there may be more or fewer than four side indentations 34. In addition, there may be side indentations on only one of the inner side surfaces of the protective wall 22. There may also be side indentations along the shorter side surfaces of the protective wall 22. The size and number of the side indentations 34 can be selected according to an estimated amount of adhesive material that will be used to attach a semiconductor die 24 to the die pad 26.

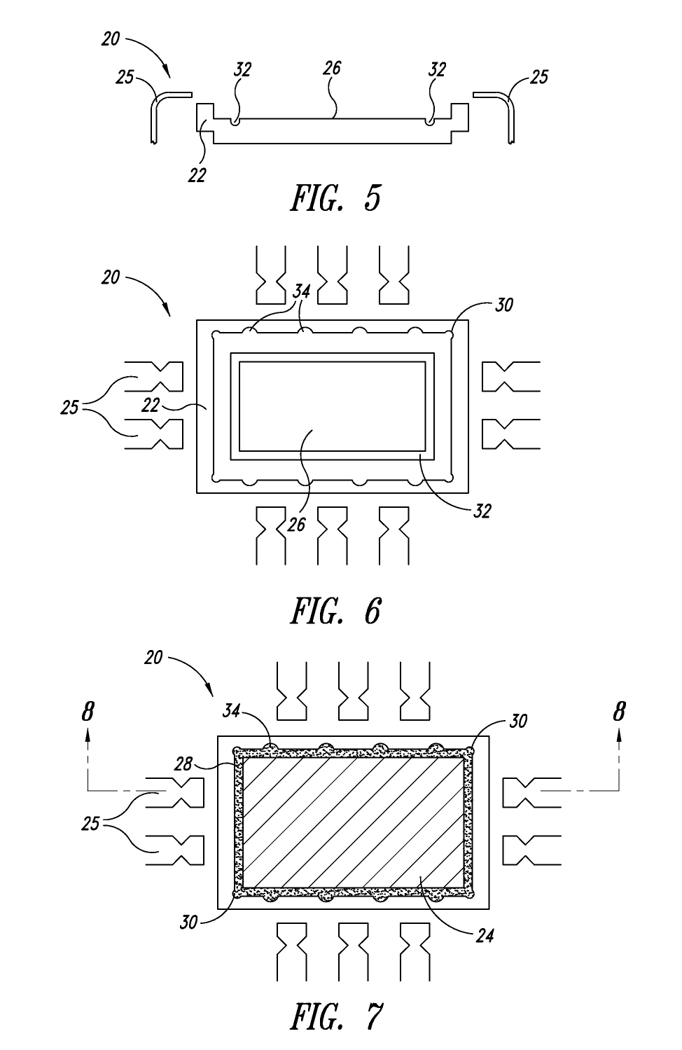

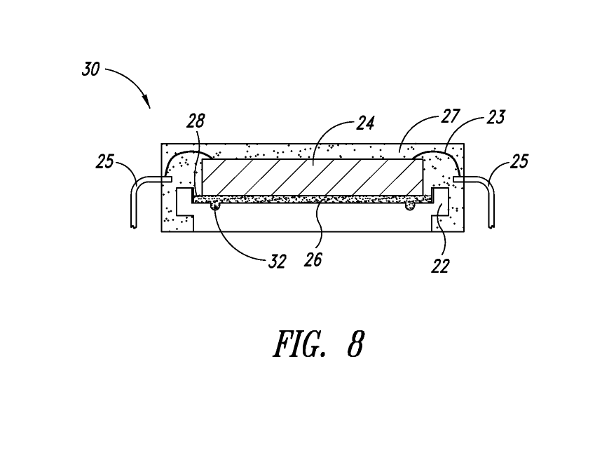

FIG. 7 is a top view of the integrated circuit package 20 of FIG. 6 after the adhesive material 28 and the semiconductor die 24 have been placed on the die pad 26 according to one embodiment. The integrated circuit package 20 includes corner indentations 30 and side indentations 34 in the protective wall 22. When the semiconductor die 24 is placed on the adhesive material 28 to couple it to the die pad 26, the adhesive material 28 is displaced and fills the side indentations and the corner indentations 30. Because the adhesive material 28 has these extra spaces in which it may flow, the adhesive material 28 does not build up along the protective wall and form an uneven surface. The adhesive material 28 also does not spill over the top of the protective wall 22. While the side indentations 34 and corner indentations 30 have been shown as having a generally round cross section, other cross sections are possible. For example, the corner indentations 30 and/or the side wall indentations 34 may include rectangular cross sections, triangular cross sections, or other uneven cross sections. The size, number, and spacings of the side indentations 34 and the corner indentations 30 may be chosen according to an estimated amount of adhesive material 28 that will be used to attach the semiconductor die 24 to the die pad 26.

FIG. 8 is a cross section of the integrated circuit package 20 of FIG. 7 according to one embodiment taken along line 8-8. The integrated circuit package 20 of FIG. 7 includes groove 32 formed in the die pad 26. Adhesive material 28 has been placed on the die pad 26. The semiconductor die 24 has been placed on the adhesive material 28 to attach it to the die pad 26. The semiconductor die 24 is electrically connected to leads 25 by bonding wire 23. The semiconductor die 24 may also be electrically connected to the protective wall 22 by bonding wire 23.

When the semiconductor die 24 is placed on the adhesive material 28, the adhesive material 28 is displaced and fills the groove 32. Because the adhesive material 28 is able to fill the groove 32, the adhesive material 28 does not build up an uneven surface adjacent the protective wall 22. Furthermore, the adhesive material 28 does not spill over the protective wall 22. Because the surface of the adhesive material 28 is flat, the semiconductor die 24 will experience less tension and other forces which may cause bending and stress in the semiconductor die 24 and may cause cracks to form in the semiconductor die 24. Because the adhesive material 28 does not spill up and over the protective wall 22, delamination of the molding compound 27 from the side wall 22 is less likely to occur. Corner indentations 30 and side indentations 34 may also be present in the integrated circuit package 20 of FIG. 7, though not shown in this view. The corner indentations 30 and the side indentations 34 are also filled with the adhesive material 28, enabling the adhesive material to form a flat surface and not spill up and over the protective wall 22. Alternatively, the integrated circuit package 20 may include only the groove 32 and the corner indentations 30. Or the integrated circuit package 20 may include the groove 32 and the side indentations 34. Many other configurations are possible as will be apparent to those of skill in the art in light of the present disclosure.

While the integrated circuit package 20 has been shown as a leadframe package, many other package configurations are possible. In one embodiment, the semiconductor die 24 is placed on a substrate 26 other than a leadframe. For example, the semiconductor may be placed on an organic substrate. The protective side wall 22 may also be formed of the organic substrate or may be attached to the substrate surrounding the semiconductor die 24 or the area on which the semiconductor die 24 will be placed. Dielectric substrates, silicon substrates, or any other suitable substrates may be used as will be apparent to those of skill in the art in light of the present disclosure. As illustrated in the Figures, the integrated circuit package 20 has shown a leadframe configuration in which the die pad 26 and the protective wall 22 are integral with each other. In such an embodiment, the protective wall 22 and the die pad 26 may be formed of copper or another electrically conductive and thermally conductive material. The integrated circuit 24 may be wire bonded to the protective wall 22 in order to provide a ground contact for the semiconductor die 24. In other embodiments, a leadframe configuration may be used in which the protective wall 22 is not conductive or integral with the die pad 26. In one embodiment, the die pad 26 is not a conductive material.

In one embodiment the integrated circuit package 20 is a ball grid array. In one embodiment the integrated circuit package 20 is pin grid array or any other suitable package type. Many materials and configuration may be used to form an integrated circuit package 20 according to the present disclosure. All such embodiments fall under the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device comprising:
a die pad having a top surface;
a semiconductor die on the top surface of the die pad;
a support wall surrounding the die pad;
a molding compound covering the support wall and the semiconductor die; and
an indentation in the support wall at an inner corner of the support wall adjacent a corner of the semiconductor die.

2. The device of claim 1 comprising an adhesive material coupling the semiconductor die to the top surface of the die pad.

3. The device of claim 2 comprising a groove in the top surface of the die pad below the semiconductor die.

4. The device of claim 3 wherein the adhesive material fills the groove.

5. The device of claim 2 wherein the adhesive material fills the indentation.

6. The device of claim 1 comprising conductive leads covered in the molding compound and coupled to the semiconductor die by wire bonds.

7. The device of claim 1 wherein the protective wall comprises a plurality of indentations each at a respective corner of the protective wall and adjacent a respective corner of the semiconductor die.

8. The device of claim 1 comprising an indentation on an inner wall of the protective wall adjacent a side of the semiconductor die.

9. A method comprising:
forming a die pad having a top surface configured to receive a semiconductor die;
forming a protective wall surrounding the die pad; and
forming an indentation on an inner corner of the protective wall adjacent a corner of the die pad.

10. The method of claim 9 comprising:
placing an adhesive material on the die pad; and
placing the semiconductor die on the adhesive material to couple the semiconductor die to the die pad.

11. The method of claim 10 comprising encapsulating the semiconductor die in a molding compound.

12. The method of claim 9 wherein the adhesive material fills the indentation.

13. The method of claim 9 comprising:
forming a groove in the top surface of the die pad prior to placing the adhesive material on the die pad;
placing the semiconductor die over the groove; and
filling the groove with the adhesive material.

14. The method of claim 9 comprising forming a plurality of indentations along on an inner surface of the protective wall adjacent a length of the die pad.

15. A device comprising:
a rectangular die pad having a top surface;
a rectangular protective wall surrounding the die pad and having four inner corners; and
a plurality of corner indentations on the inner corners of the protective sidewall.

16. The device of claim 15 wherein the protective wall includes four inner sidewalls, each inner sidewall including a plurality of side indentations.

17. The device of claim 16 comprising:
an adhesive material on the die pad and filling the corner indentations and the side indentations; and
a semiconductor die on the adhesive material and coupled to the top surface of the die pad by the adhesive material.

18. The device of claim 17 comprising a groove in the top surface of the die pad below the semiconductor die, the groove being filled with the adhesive material.

19. The device of claim 18 wherein the groove extends around perimeter of the semiconductor die.
